(19) United States
(12) Patent Application Publication
(10) Pub. No.: US 2009/0142876 A1
(43) Pub. Date: Jun. 4, 2009

(54) INK COMPOSITION AND FABRICATION METHOD FOR COLOR CONVERSION FILM

(75) Inventors: Chi-Shen Tuan, Hsinchu (TW); Wan-Jung Teng, Hsinchu Hsien (TW); Feng-Mei Wu, Hsinchu (TW); Mei-Ling Chou, Hsinchu (TW)

Correspondence Address: PAI PATENT & TRADEMARK LAW FIRM, 1001 FOURTH AVENUE, SUITE 3200, SEATTLE, WA, 98154, US

(73) Assignee: INDUSTRIAL TECHNOLOGY RESEARCH INSTITUTE, Hsinchu County (TW)

(21) Appl. No.: 12/204,702

(22) Filed: Sep. 4, 2008

(30) Foreign Application Priority Data
Nov. 30, 2007 (TW) 096145572

(51) Int. Cl. H01L 33/00; G02B 5/23

(52) U.S. Cl. 438/70; 252/586; 257/E33.061

(57) ABSTRACT

An ink composition of a color conversion film is disclosed. The ink composition includes a fluorescent polymer (Formula I, II, III), an aromatic transparent unsaturated resin containing a phenyl or fluorene functional group (Formula IV, V), and a solvent of a cyclic compound, wherein the molecular structure of the aromatic transparent unsaturated resin is compatible to that of the fluorescent polymer. The invention further provides a fabrication method of a color conversion film including dispensing the disclosed ink composition on a substrate, and curing the ink composition to form the color conversion film.

### CROSS REFERENCE TO RELATED APPLICATIONS

This Application claims priority of Taiwan Patent Application No. 096145572, filed on Nov. 30, 2007, the entirety of which is incorporated by reference herein.

### BACKGROUND OF THE INVENTION

1. Field of the Invention

The invention relates to a color conversion film for a light emitting diode, and more particularly to an ink composition and the fabrication method of the color conversion film.

2. Description of the Related Art

In general, white light-emitting diodes (LEDs) can be formed by using a blue light from a blue LED die to excite the YAG: Ce3⁺ fluorescent powder for luminescing a yellow light and then mixing the yellow light with the unabsorbed blue light to form a white light. Additionally, white light-emitting diodes (LEDs) can be formed by using a light from a UV LED die to excite the red, green and blue (RGB) fluorescent powders and then mix the red, green and blue lights produced from the fluorescent powders to form a white light.

For the conventional fabrication method of white light-emitting diodes, the fluorescent powder needs to be mixed with a high transparent, high temperature resistant bonding agent. For example, fluorescent pigments or fluorescent dyes are mixed with epoxy resin to form a mixture to cover the LED die and then the mixture is cured to complete the LED. However, the fluorescent powder is incompatible with the bonding agent such that it does not disperse uniformly in the bonding agent and the luminescence from the LED is not uniform.

U.S. Pat. No. 4,262,206 discloses a fluorescent color conversion substrate which is formed by using an organic fluorescent dye mixed with transparent polymers, dissolved in a solvent and then coated on a transparent substrate. The patent disclosed a method to obtain a broad wavelength emission with various fluorescent dyes coating. The method is very complicated and the conversion efficiencies are not good. U.S. Pat. No. 5,966,393 discloses using a inorganic blue LED to excite poly(phenylene vinylene) or polyphenylene derivatives to produce a light and then mix the light with the blue light to form a white light. However, this method does not disclose the incompatible problems between fluorescent polymers and transparent resin. U.S. Patent No. 20040231554 discloses using a dual wave band fluorescent material to form an inkjet printing ink for a color conversion film. The ink is inkjet printed on an LED die to form the color conversion film. However, the inkjet printing ink can not package the LED die. Japan Patent No. 2004-362910 discloses using fluorene or benzo chromene as a host molecule for copolymerizing with other low energy gap conjugated molecules to form an electro-luminescent polymer. The electro-luminescent polymer is mixed with a high fluorescent efficient fluorescent agent and dissolved in a solvent to form a color conversion film. In this patent, a blue light fluorene polymer is used as a light source and the packaging method thereof is performed by using a transparent resin disposed on the color conversion film to resist the oxygen in the environment. As the same as U.S. Pat. No. 5,966,393, the patent does not disclose the incompatible problems between fluorescent polymers and encapsulation resin. And the device of this patent is complicated. Taiwan Patent No. M264659 discloses using phenylenevinylene based fluorescent polymer thermal-deposited on a light-emitting surface of an inorganic LED die and then packaging the die with a transparent resin. However, the fluorescent polymers are easy to degrade and the process thereof is also complicated.

### PACKAGING BRIEF SUMMARY OF THE INVENTION

The invention utilizes a fluorescent polymer and an encapsulant material which is compatible with the fluorescent polymer to dissolve together in a solvent to form an ink for a color conversion film. The ink is disposed on an LED die or a transparent substrate by an inkjet printing, offset printing, screen printing or direct coating process to form the color conversion film.

The invention provides an ink composition of a color conversion film. The ink composition comprises a fluorescent polymer, an aromatic transparent unsaturated resin containing a phenyl or fluorene functional group, and a solvent of a cyclic compound, wherein the molecular structure of the aromatic transparent unsaturated resin is compatible to that of the fluorescent polymer.

The invention further provides a fabrication method of a color conversion film comprising dispensing the disclosed ink composition on a substrate, and curing the ink composition to form the color conversion film.

A detailed description is given in the following embodiments with reference to the accompanying drawings.

### BRIEF DESCRIPTION OF THE DRAWINGS

The invention can be more fully understood by reading the subsequent detailed description and examples with reference to the accompanying drawings, wherein:

FIG. 1 shows a schematic cross section of a color conversion film on an LED die according to one embodiment of the invention;

FIG. 2 shows a schematic cross section of a color conversion film on a transparent substrate according to one embodiment of the invention;

FIG. 3 shows a schematic plane view of a color filter formed by a color conversion film disposed on a transparent substrate according to one embodiment of the invention;

FIG. 4 shows a schematic plane view of a color filter formed by a color conversion film disposed on a transparent substrate according to another embodiment of the invention;

FIG. 5 shows a schematic structure of a color conversion film disposed on a light guide plate with a blue light LED backlight according to one embodiment of the invention;

FIG. 6 shows a UV-Vis absorbed spectrum and a PL (photoluminescence) spectrum of a yellow light biphenyl fluorine polymer according to the Preparing Example 7 of the invention; and

FIG. 7 shows a white luminescence spectrum of a blue light LED backlight with a color conversion film of a yellow light polymer according to the Example 6 (blue LED+UVP5) of the invention.

### DETAILED DESCRIPTION OF THE INVENTION

The following description is of the best-contemplated mode of carrying out the invention. The description is provided for illustrating the general principles of the invention and is not meant to be limiting. The scope of the invention is best determined by reference to the appended claims.

The invention utilizes a high dissolvent fluorescent polymer as a fluorescent agent. A transparent unsaturated resin containing a phenyl or fluorene functional group has a molecular structure compatible to that of the fluorescent polymer, such that the transparent unsaturated resin can be mixed with the fluorescent polymer for uniformly dissolving in a solvent to form an ink composition of a color conversion film. The ink composition has a uniform dispersion of the fluorescent agent and can overcome the disadvantages of the conventional fluorescent powder which is not compatible to a bonding agent.

The ink composition of a color conversion film of the invention at least comprises a fluorescent polymer (Formula I, II, III), an aromatic transparent unsaturated resin containing a phenyl or fluorene functional group (Formula IV, V), and a solvent of a cyclic compound. Moreover, the ink composition further comprises a photoinitiator or a thermal curing agent and a thermal curing accelerator. The fluorescent polymer can use a conjugated molecule of phenanthrene derivatives or 9,9-diphenyl-fluorene as a core and add the other efficient fluorescent aromatic molecules for copolymerizing, such that the fluorescent color thereof can be adjusted and the fluorescent efficiency can be enhanced. The fluorescent polymer can have a structure of Formula (I) as below:

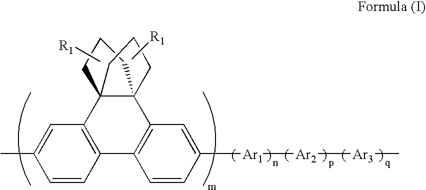

The phenanthrene derivative copolymer of Formula (I) is consisted of a phenanthrene derivative monomer unit and more than one of phenyl, naphthyl, heterocyclic group, polycyclic aromatic group and polycyclic heterocyclic group containing at least one conjugated group. The phenanthrene derivative copolymer has a molecular weight (Mw) of 5K-1000K, and more preferred of 50K-300K.

Moreover, the fluorescent polymer of the invention can have a structure of Formula (II) as below:

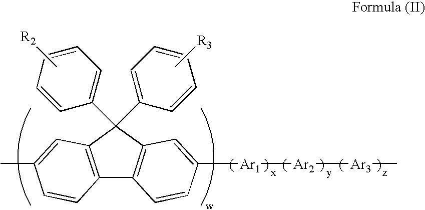

The biphenyl fluorene copolymer of Formula (II) is consisted of a biphenyl fluorene derivative monomer unit and more than one of phenyl, naphthyl, heterocyclic group, polycyclic aromatic group and polycyclic heterocyclic group containing at least one conjugated group. The biphenyl fluorene derivative copolymer has a molecular weight (Mw) of 5K-1000K, and more preferred of 50K-300K.

Each Ar₁, Ar₂, and Ar₃ of Formula (I) and Formula (II) is independently selected from a group consisted of the functional groups as below:

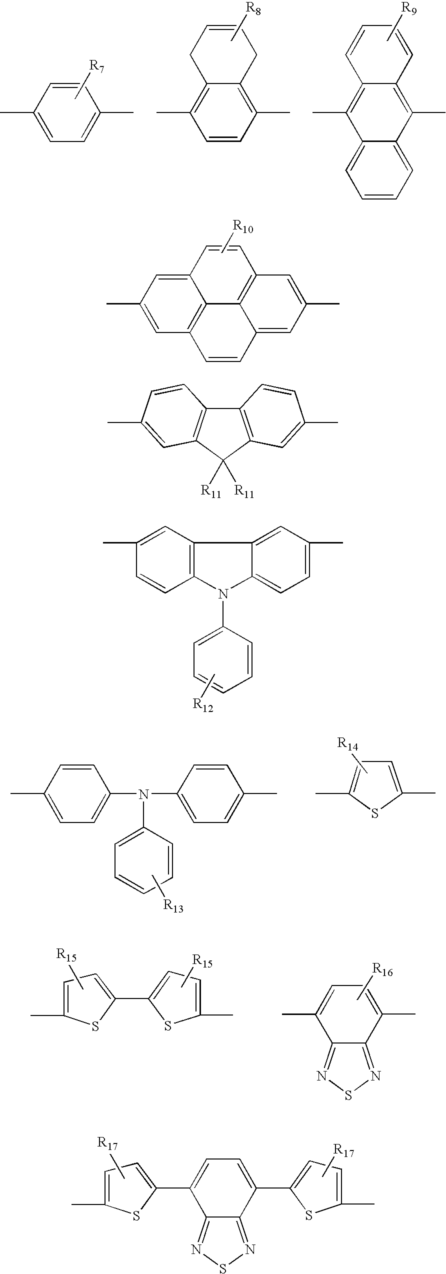

Each R₁-R₃ of the fluorescent polymer of Formula (I) and Formula (II) is independently hydrogen, hydroxyl, carboxyl group, aldehyde group, keto group, straight-chain or branched-chain C₁₋₂₂ alkyl, straight-chain or branched-chain C₁₋₂₂ alkoxy, ortho-, meta-, or para-alkyl phenoxy. Each R₇—R₁₇ is independently hydrogen, straight-chain or branched-chain C₁₋₂₂ alkyl, or straight-chain or branched-chain C₁₋₂₂ alkoxy. Each m, n, p, and q of formula (I) and each w, x, y, and z of formula (II) is the number of repeated units, wherein the ratio of m in formula (I) and the ratio of w in formula (II) are at least more than 10%, and more preferred more than 50%.

Additionally, the fluorescent polymer can be a poly(phenylene vinylene) (PPV) polymer having a structure of Formula (III) as below:

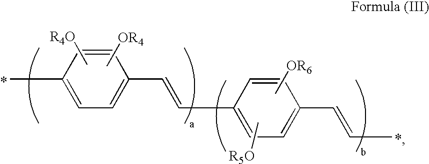

wherein each R₄˜R₆ is independently straight-chain or branched-chain C₁₋₂₂ alkyl, ortho-, meta-, or para-alkyl phenyl or ortho-, meta-, or para-alkyl phenoxy, and each a and b of Formula (III) is the number of repeated units. The ratio of a in Formula (III) is at least more than 10%, and more preferred more than 50%. The fluorescent polymer of Formula (III) has a molecular weight (Mw) of 5K˜1500K, and more preferred of 400K˜800K.

The monomers 1˜7 (m1˜m7) have molecular structures as below:

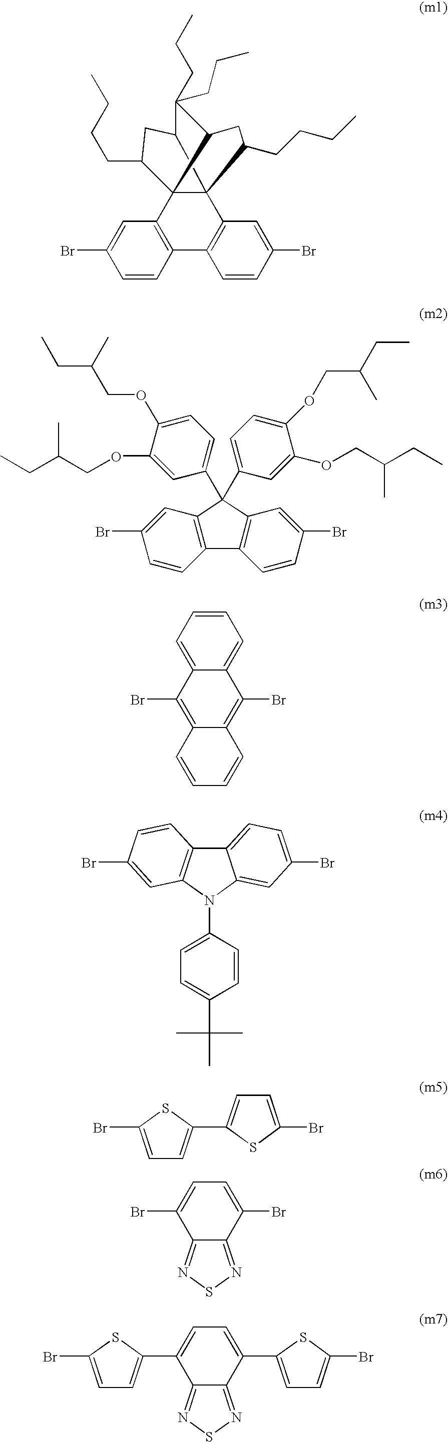

The copolymer derivatives of the phenanthrene fluorescent polymer of Formula (I) can be formed from copolymerizing the monomer m1 with the monomers m2˜m7 of different ratios by Yamamoto coupling reaction to obtain a green light, a yellow light and a red light fluorescent polymers.

The copolymer derivatives of the biphenyl fluorene fluorescent polymer of Formula (II) can be formed from copolymerizing the monomer m2 with the monomers m3˜m7 of different ratios by Yamamoto coupling reaction to obtain a green light, a yellow light and a red light fluorescent polymers.

The monomers 8 and 9 (m8 and m9) have molecular structures as below:

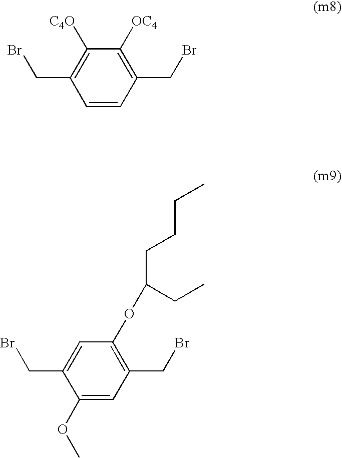

The copolymer derivatives of the PPV fluorescent polymer of Formula (III) can be formed from copolymerizing the monomer m8 with the monomer m9 of different ratios by a Gilch dehydrohalogenation condensation polymerization to obtain a green light, a yellow light and an orange light fluorescent polymer.

The monomers m3 (9,10-Dibromoanthracene, CAS No. 523-27-3), m5 (5,5′-Dibromo-2,2′-bithiophene, CAS No.4805-22-5), and m9 (2,5-Bis(bromomethyl)-1-methoxy-4-(2-ethylhexyloxy) benzene, CAS No.2096255-56-2) are taken from Aldrich Co. and then purified by re-crystallization. The other monomers m1, m2, m4, m6, m7, and m8 are synthesized by the methods of the Preparing Examples described later. The monomers m1˜m7 can be copolymerized to form a green light, a yellow light and an red light phenanthrene or biphenyl fluorene polymer derivatives by Yamamoto coupling reaction. The monomers m8 and m9 can be copolymerized to form a green light, a yellow light and an orange light PPV polymer derivative by a Gilch dehydrohalogenation condensation polymerization.

The fluorescent polymers of the ink composition of the invention have an ultraviolet-visible (UV-Vis) absorption spectrum at about 350 to 490nm. The fluorescent polymers have a molecular weight (Mw) of about 10⁴˜10⁵, and the fluorescent polymer is about 0.5 to 10% by weight in the ink composition.

The transparent resin of the ink composition of the invention can be selected from an aromatic unsaturated resin which has a molecular structure compatible to that of the above fluorescent polymers. The molecular structure of the transparent aromatic unsaturated resin contains a phenyl or fluorene functional group. The transparent resin can be a thermal curable fluorene or phenyl epoxy resin which has a structure of Formula (IV) as below:

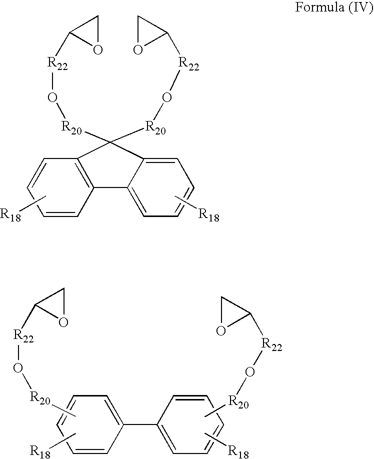

, wherein each R₁₈ is independently hydrogen, straight-chain or branched-chain C₁₋₆ alkyl, straight-chain or branched-chain C₁₋₆ alkoxy, ortho-, meta-, or para-alkyl phenyl, ortho-, meta-, or para-alkyl phenoxy, or ortho-, meta-, or para-phenolic group, and each R₂₀ is independently C₁₋₆ carbon chain, ortho-, meta-, or para-phenyl, ortho-, meta-, or para-phenolic group, ortho-, meta-, or para-alkyl phenyl, and each R₂₂ is independently C₁₋₆ carbon chain.

The transparent resin of the ink composition of the invention can be a photo curable transparent unsaturated resin which has a structure of Formula (V) as below:

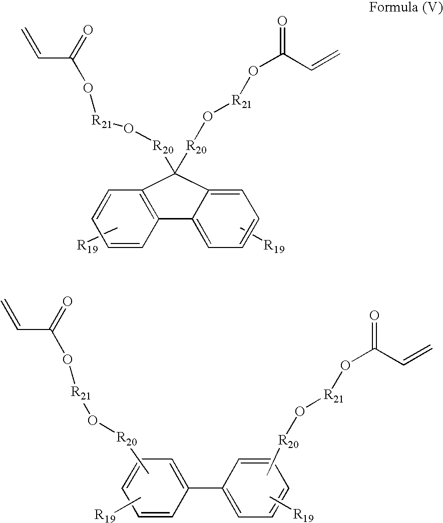

, wherein each R₁₉ is independently hydrogen, straight-chain or branched-chain C₁₋₆ alkyl, straight-chain or branched-chain C₁₋₆ alkoxy, ortho-, meta-, or para-alkyl phenyl, or ortho-, meta-, or para-phenolic group, and each R₂₀ is independently C₁₋₆ carbon chain, ortho-, meta-, or para-phenyl, ortho-, meta-, or para-alkyl phenyl, ortho-, meta-, or para-phenolic group, and each R₂₁ is independently C₁₋₆ carbon chain.

The thermal curable transparent unsaturated resin of Formula (IV) is such as below:

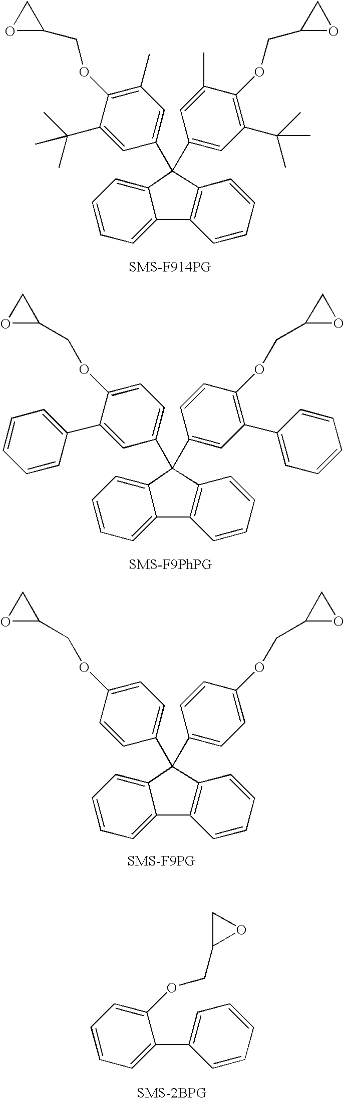

The above examples of epoxy resin containing a phenyl or fluorene functional group are the products of Sun Moon Star Technology Co., Ltd. (S.M.S. Group).

A thermal curing agent used for the thermal curable transparent unsaturated resin of Formula (IV) is such as dicyandiamide (DICY), phthalic anhydride, or 4,4-methylenedianiline (MDA) as below:

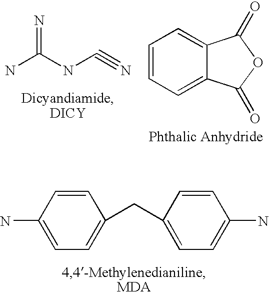

A thermal curing accelerator used for the thermal curable transparent unsaturated resin of Formula (IV) is such as benzyl-dimethylamine (BDMA) or 2, 4, 6 tris(dimethylaminomethyl) phenol as below:

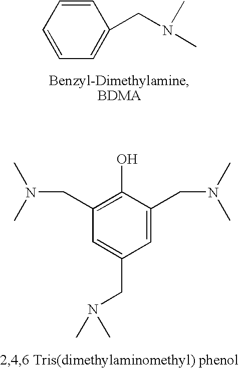

The thermal curing agent and the thermal curing accelerator as the above can be the products of Echo Chemical Co. The SMS system epoxy resin containing a phenyl or fluorene functional group can be the products of S.M.S. Tech. Co., Ltd.

The photo curable transparent resin of Formula (V) is such as below:

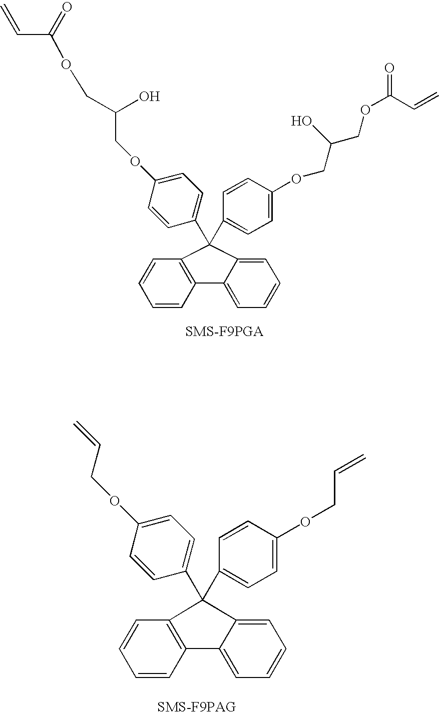

The above compounds are the products of, S.M.S. Tech. Co., Ltd. wherein the product of SMS-F9PGA is a transparent liquid containing 50% of propylene glycol monoethyl ether acetate (PGMEA).

A photo curing agent used for the photo curable transparent resin of Formula (V) is such as KT37 as below:

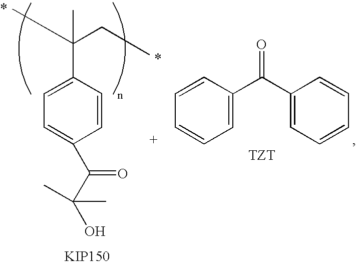

wherein n is the number of repeated units. KT37 is the product of Sartomer Co.

The transparent resin of the ink composition can be about 10˜40% by weight, and more preferred uses the thermal curable transparent resin together with the photo curable transparent resin.

The fluorescent polymer and the transparent resin as previously described, can be dissolved in a solvent of a cyclic compound together. The solvent of a cyclic compound can be one or more than one solvent having a boiling point of 60˜200° C. The viscosity and the surface tension of the ink can be adjusted by the ratio of the fluorescent polymer, the transparent resin and the solvent, such that the ink is suitable for various liquid processes. The solvent of the ink composition can be about 40˜80% by weight.

For the ink used in a coating process, the preferred solvent is a volatile solvent with a high volatility, for example, tetrahydrofuran (THF), anisole, cyclohexone, pyridine, pyrrolidine, toluene, or p-xylene. The ink has a viscosity of about 20˜100 cps. For the ink used in an inkjet printing process, the preferred solvent is a solvent with a low volatility, for example, phenol, o-xylene, anisole, 1,3,5-, 1,4,5- or 1,2,3-trimethyl benzene, aniline, methylaniline, dimethylaniline, toluidine or the combinations thereof. The ink has a viscosity of about 2-20cps.

In addition to the fluorescent polymer, the transparent unsaturated resin, the curing agent, the curing accelerator, the photoinitiator, and the solvent as previously described, the ink composition of the invention further comprises an anti-oxidant and an optical micro-particle having a diameter of about 0.1˜1 μm. The anti-oxidant is such as tri(phenyl) phosphite, which is the product of Chang Chun Petro Chemical Co. and has a structure as below:

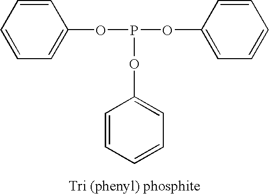

The addition of the optical micro-particle is for light scattering, such that a uniform light color can be achieved. The optical micro-particle may be polyethylene (PE), polymethylmethacrylate (PMMA), SiO₂ or the combinations thereof, and the SiO₂ micro-particle is more preferred which can be the product of Echo Chemical Co.

In the ink composition, the curing agent can be about 0.5˜3% by weight, the curing accelerator can be about 0.05˜0.3% by weight, the photoinitiator can be about 1˜5% by weight, the anti-oxidant can be about 0.05˜0.5% by weight, and the optical micro-particle can be about 1˜5% by weight.

An ink composition solution of the invention can be dispensed on a blue LED die, a UV LED die, a light guide plate or a transparent substrate by a liquid process. The liquid process may be an inkjet printing, screen printing, gravure printing, flexographic printing, plate printing, stamping, spray coating, blade coating or die coating process. The ink composition solution is cured by heating or UV illuminating through a cross linking reaction to form a color conversion film or a color mixing layer.

Moreover, the molecular structure of the fluorescent polymer in the ink composition can be adjusted for absorbing a first color light having wavelength of about 360˜420 nm from the UV LED die. Then, the fluorescent polymer can be excited to produce a second light source of three colors containing a red, a green and a blue light. The second light source of three colors can be mixed to produce a white light source.

For use in the inkjet printing process, the viscosity of the ink can be adjusted to about 2˜20 cps and the solvent of the ink composition can be selected from a solvent with a high boiling point and a low volatility.

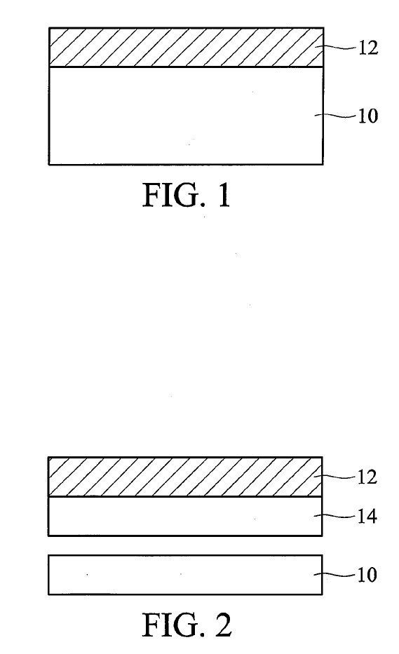

Referring to FIG. 1, a schematic cross section of a color conversion film on an LED die according to one embodiment of the invention is shown. The ink composition of the invention can be coated on a blue LED die or a UV LED die 10. Then, through a baking process, the ink is cured by a crosslinking reaction to form a color conversion film or a color mixing layer 12 for making various colors of LED light sources. The blue LED die may be InGaN LED die or other blue LED dies. The UV LED die may be AlGaN LED die or other UV LED dies. A white LED can be fabricated by coating the ink composition of the invention on the blue or UV LED die to form a color conversion film. The color temperature of the white LED can be adjusted by the ratios of red, green, and blue fluorescent polymers in the ink composition. The color temperature of the white LED is between about 2000K and 8000K.

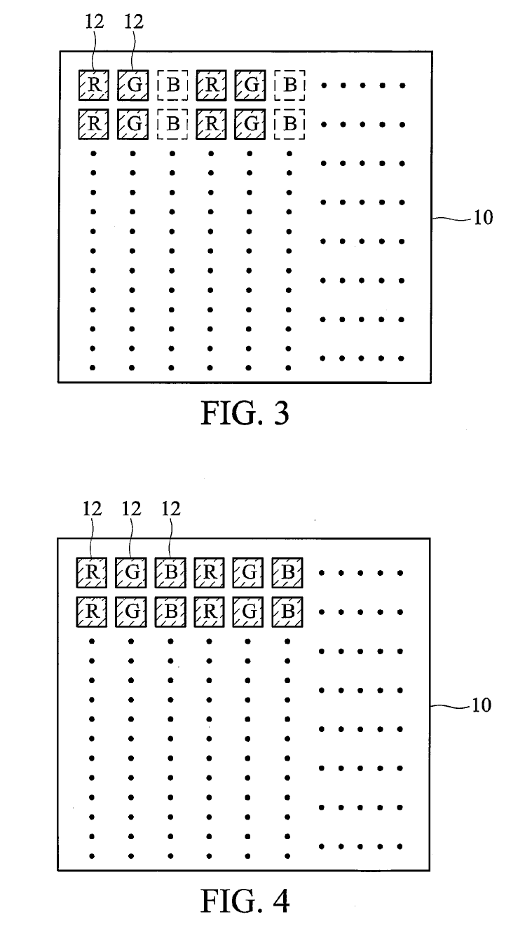

Referring to FIG. 2, a schematic cross section of a color conversion film on a transparent substrate according to one embodiment of the invention is shown. The ink composition of the invention can be printed or coated on a transparent substrate 14. After baking, the ink is cured by a crosslinking reaction to form a color conversion film or a color mixing layer 12 on the transparent substrate. Moreover, a blue LED or a UV LED is disposed under the transparent substrate 14 as a backlight source 10 to form various colors of thin plane light sources. Additionally, the ink composition can be coated on the transparent substrate by a digital inkjet printing technology according the patterns, photographs or pictures to fabricate an artistic light source having a special pattern.

Moreover, the ink composition of the invention can be inkjet printed on a transparent substrate to fabricate a color conversion film having a form of an array of a plurality of pixels. Then, a blue LED or a UV LED can be disposed under the transparent substrate as a backlight source. The blue LED or the UV LED light source can be transferred into a light source containing a red, a green and a blue lights by the fluorescent polymer of the ink composition. Therefore, the color conversion film of the invention can be used in the liquid crystal displays as color filters.

Referring to FIG. 3, a schematic plane view of a color filter formed by a color conversion film disposed on a transparent substrate according to one embodiment of the invention is shown. In this embodiment, the molecular structure of the fluorescent polymer in the ink composition can be adjusted for forming a red light and a green light fluorescent polymer. Then, the ink compositions containing the red light and the green light fluorescent polymers are inkjet printed on a red pixel area R and a green pixel area G of a transparent substrate 10, respectively, to form a color conversion film 12. A blue pixel area B of the substrate is not covered with the ink. Then, a blue LED light source is disposed under the transparent substrate as a backlight source. The blue light from the LED light source is transferred into a red light and a green light through the color conversion film on the transparent substrate, and the blue light pass through the transparent substrate. Accordingly, the color conversion film of the invention can be used in the liquid crystal displays as color filters.

Referring to FIG. 4, a schematic plane view of a color filter formed by a color conversion film disposed on a transparent substrate according to another embodiment of the invention is shown. In this embodiment, the molecular structure of the fluorescent polymer in the ink composition can be adjusted for forming a red light, a green light and a blue light fluorescent polymer. Then, the ink compositions containing the red light, the green light and the blue light fluorescent polymers are inkjet printed on a red pixel area R, a green pixel area G and a blue pixel area B of a transparent substrate 10, respectively, to form a color conversion film 12. Then, a UV LED light source is disposed under the transparent substrate as a backlight source. The UV light from the LED light source is transferred into a red light, a green light and a blue light through the color conversion film on the transparent substrate. Accordingly, the color conversion film of the invention can be used in the liquid crystal displays as color filters.

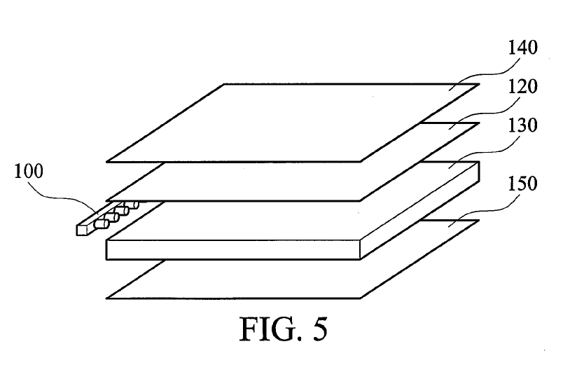

Referring to FIG. 5, a schematic structure of a color conversion film disposed over a blue backlight module according to one embodiment of the invention is shown. The ink composition of the invention can be dispensed on a light guide plate 130 through various printing or coating processes. After baking or photo curing, the ink is cured by a crosslinking reaction to form a color conversion film or a color mixing layer 120. A blue LED or a UV LED light source 100 is disposed on the side of the light guide plate 130. The side light source 100 is guided into a first light source of a blue light or a UV light plane through the light guide plate 130. Then, the blue LED or the UV LED light source is transferred into a second light source by the fluorescent polymer of the color conversion film 120 to fabricate various colors of thin plane light sources. In general, a reflective layer 150 is disposed under the light guide plate 130 and a diffusion film 140 can be disposed over the color mixing layer 120. Additionally, the ink composition of the color conversion film of the invention also can be inkjet printed or printed on the diffusion film 140 to achieve the effect of color conversion.

Because the major molecular structure of the transparent resin is compatible to the molecular structure of the fluorescent polymer in the ink composition of the invention, no phase separation is produced after baking or UV illuminating to form a film. Therefore, a uniform color of light is achieved.

Moreover, the ink composition of the invention can be coated on the surface of the LED die directly to form a color conversion film. The transparent resin of the ink composition can protect the fluorescent polymer from oxygen and water in the air to prolong the life time of the fluorescent polymer and enhance the color stability thereof. Additionally, the transparent resin of the ink composition can overcome the disadvantages of the conventional materials, in which the fluorescent polymer is easily damaged by the UV light.

The transparent resin in the ink composition also can be used for packaging the LED die. Therefore, while using the ink composition of the invention to form a color conversion film on the LED die, the LED die would be packaged. Additionally, the liquid processes of using the ink are more convenient than the conventional LED packaging processes.

The preparing of components, the ink composition of the examples, and the related measurement results of the color conversion film formed from the ink composition of the examples are described in detail as below:

### PREPARING EXAMPLE 1

### Synthesis of Monomer m1

### 2,7-Dibromo-((9,10;9,10-(Tetra-butyl)-propano-indene)-9,10-dihydrophenanthrene)

3 grams of phenanthrene-9,10-diketone (14 mmole, manufactured by the Aldrich Co., 95%) was dissolved in 60ml HBr (48%, manufactured by the ACS Co.) and 20 ml H2SO4 (manufactured by the Merck Co.), and heated to 80° C., and a small amount of Br2 (manufactured by the ACROS Co.) was slowly added, after which the mixture was allowed to react for 24 hours. After precipitation and filtration, dibromophenanthrene-9,10-diketone was obtained. 2 grams of dimethyl 1,3-acetonedicarboxylate (11 mmole, manufactured by the ACROS Co., 95%), and a mixture of NaOH and methanol were mixed and the temperature was maintained at 60° C. After 36 hours of reaction, 10% HCl aqueous solution (37%, manufactured by the ACS Co.) was added to the reaction mixture for neutralization, and then the mixture was precipitated and filtered. The precipitate collected was dissolved by acetic acid, 300ml 10% HCl aqueous solution was added, and heated for reaction for 18 hours. Then, acetic acid and water were removed, and the product was neutralized with sodium hydrogen carbonate aqueous solution, precipitated, and filtered. After column purification, a light yellow product of 9,10:9,10-bis(2-oxopropano-indene)-2,7-dibromo-9,10-dihydrophenanthrene was given.

1 gram of bis(2-oxopropano-indene)-2,7-dibromo-9,10-dihydrophenanthrene (2.2 mmole) was placed in a dual-neck vase, filled with nitrogen, 20 ml of anhydrous THF (manufactured by the Aldrich Co.) was added, the mixture was stirred and cooled down to −78° C. 3 ml of Lithium diisopropylamide (LDA) (2M, manufactured by the Aldrich Co.) was slowly added, stirred at −78° C. for reaction for 1 hour. 5 ml of butyl bromide dissolved in anhydrous THF (2.4 mmole, Aldrich) was slowly added, stirred for 1 hour, heated to room temperature for reaction for 24 hours, NH₄Cl aqueous solution was added to stop the reaction, extracted by EA and water, and then dehydrated with magnesium sulfate, giving an intermediate containing diketone and butyl. 3 grams of the intermediate containing diketone and butyl and 150 ml of ethylene glycol (ACROS) were mixed, 2.4 grams of hydrazine (N₂H₄.H₂O, Merck) was added, stirred for 10 minutes, 2.6 grams of KOH (Aldrich) was added, heated to 180° C. for reaction for 15 hours, then cooled down to room temperature. A large amount of water was added for diluting, giving a solid, wherein the solid was collected, dissolved with a small amount of dichloromethane, and separated by a column purification, giving 1.7 grams of a white solid. 1H NMR (400 MHz, CDCl3): δ (ppm) 7.34˜7.25 (m, 3H), 7.23˜7.13 (m, 3H), 1.86-1.23 (m, 25H), 0.94˜0.84 (m, 9H).

The following reaction scheme illustrates the preparation of monomer m1:

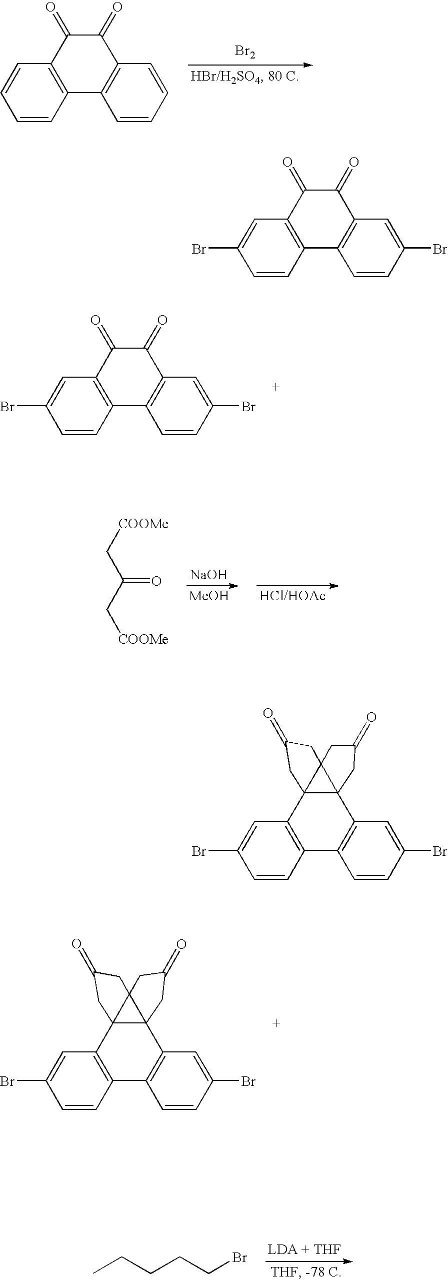

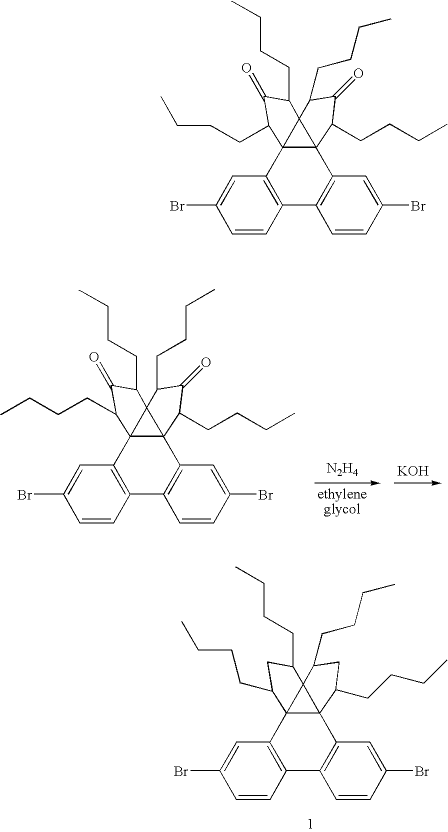

### PREPARING EXAMPLE 2

### Synthesis of Monomer m2

### 2,7-Dibromo-(9,9′-Bis(3,4-di(2-methyl-butoxyphenyl)fluorene

76 grams of CrO3 (760 mmol, Aldrich), 400 ml of acetic acid were placed in a reaction vase, 80 grams of dibromo fluorine (248.5 mmol, Aldrich), 300 ml of dichloromethane were mixed to add in the reaction vase, stirred in a ice bath for 1 hour, stirred at room temperature for 1 hour, added water to stop the reaction, and filtered, giving a solid. Water was used to wash the remaining acetic acid and then vacuum dried, giving a yellow solid of 2,7-Dibromo-fluoren-9-one. 0.9 grams of 2,7-Dibromo-fluoren-9-one (1.33 mmole), 0.9 grams of catechol (8 mmole, TCI), 0.75 grams of methanesulfonic acid (8 mmole, Merck) were dissolved in 5 ml of carbon tetrachloride (Aldrich), stirred at 100° C. for 24 hours, cooled down to room temperature, and added 50 ml of NaHCO3(aq), (Merck) to stop the reaction. EtOAc (Aldrich) was used for extraction of the organic layer, magnesium sulfate was used for drying, and then the resulted product was concentrated and column purified, giving a black pink solid of 2,7-Dibromo-9,9-bis-(benzene-1,2-diol)-fluorene. 2 grams of 2,7-Dibromo-9,9-bis-(benzene-1,2-diol)-fluorene (3.70 mmole), 3.1 grams of K2CO3 (22.2 mmole, ACROS), 4.5 grams of toluene-4-sulfonic acid 2-methyl-butyl ester (C5H11OTs, 18.5 mmole, formed from C5H11OH and TsCl) were dissolved in 20 ml DMF (10 ml/1 g SM, ACROS.), stirred at 100˜120° C. for 18 hours, cooled down to room temperature, and added 50 ml of water to stop the reaction. 50 ml of EtOAc (ACROS) was used for extraction for three times, and then the organic layers were combined, dried by magnesium sulfate, concentrated, and column purified, giving a brown liquid, and then washed by ethanol several times, giving a dense brown material, and vacuum dried ethanol, giving a light brown solid. 1H NMR (400 MHz, CDCl3): δ (ppm) 7.529 (d, 2H, 2.0 Hz), 7.453 (s, 2H), 7.415 (d, 2H, 2.0 Hz), 6.707 (d, 2H, 2.2 Hz), 6.666 (d, 2H, 8.4 Hz), 6.529 ( q, 2H, 3.682 ( m, 8H, 1.799 ( m, 4H ), 1.233 ( m, 8H, 1.21 ( m, 12H),

The following reaction scheme illustrates the preparation of monomer m2:

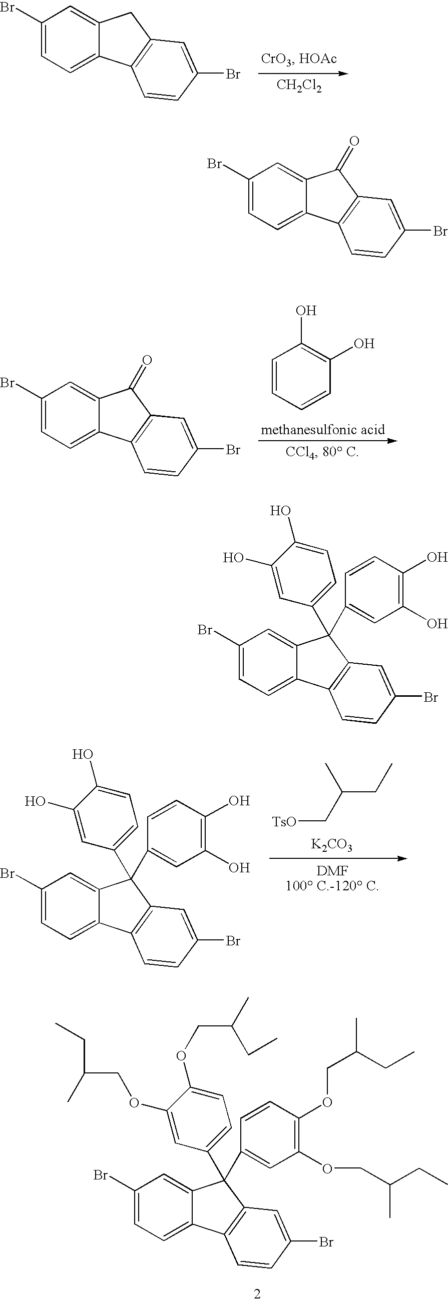

### PREPARING EXAMPLE 3

### Synthesis of Monomer m4

### 3,6-Dibromo-9-(4-tert-butyl-phenyl)-carbazole

2 grams of Carbazole (Aldrich), 0.1343 grams of Palladium(II) propionate, (Pd(OAc)2, Aldrich), 2.529 grams of tert-butyl sodium (Aldrich) were placed in a tri-neck vase. Under nitrogen, 2.55 grams of 1-Bromo-4-tert-butylbenzene (Aldrich), 0.134 grams of Tributylphosphine ((t-Bu)3P, Aldrich), 75 ml of O-xylene (Across) were added in the tri-neck vase, heated to 125° C. for reaction overnight, filtered, washed by THF, added EA to dissolve the solid part in the vase, filtered, washed by n-hexane, and re-crystallization purified, giving a white solid of 9-(4-tert-butyl-phenyl)-carbazole. 2.5 grams of 9-(4-tert-butyl-phenyl)-carbazole, 2.973 grams of N-Bromosuccinimid (NBS, Fluka), 40 ml of Dimethyl formaide (DMF, TEDIA) were placed in a single-neck vase, at room temperature for reaction overnight. After the reaction was completed, water was added, the resulted product was stirred, filtered, washed by water, precipitated, and filtered, giving a solid, washed by n-hexane, and heated to dry, giving a white solid. 1H NMR (400 MHz, CDCl3): δ (ppm) 7.27 (d, J=2.4, 2H, 7.42 (d, J=2.0, 2H, 7.50 (d, J=6.8, 2H , 7.62 (d, J=2.0, 2H), 8.199 (s, 2H ) 1.415 (s, 9H).

The following reaction scheme illustrates the preparation of monomer m4:

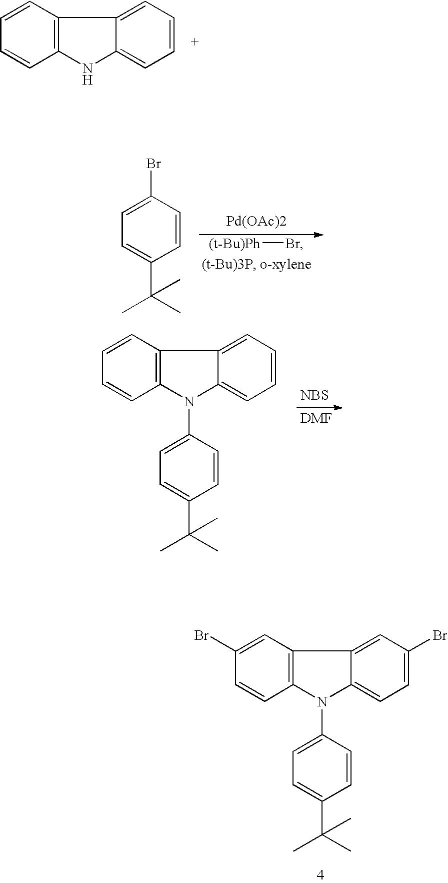

### PREPARING EXAMPLE 4

### Synthesis of Monomer m6

### 4,7-Dibromo-benzothiadiazole

13.6 grams of benzothiadiazole (Aldrich), 100 ml of Dichloromethane (CH2Cl2, Merck) were stirred until dissolved completely, 60 ml of HOAc (Merck) was added, and stirred at room temperature. 50 ml of HOAc and 40 ml of Br2 (Merck) were slowly added in the solution, at room temperature for reaction overnight. After the reaction was completed, the product was filtered and the collected solid was washed by ether, dried, and re-crystallized with IPA (ACROS), giving a white crystal. 1H NMR (400 MHz, CDCl3): δ (ppm) 7.724 (s, 2H).

The following reaction scheme illustrates the preparation of monomer m6:

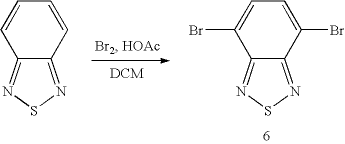

### PREPARING EXAMPLE 5

### Synthesis of Monomer m7

### 4,7-Bis-(5 -bromo-thiophen-2-yl)-benzo[1,2,5]thiadiazole

1 gram of 4,7-dibromo-2,1,3-benzothiadiazole (Aldrich), 3.06 grams of 2-(tributylstannyl)thiophene (8.2 mmole, Aldrich), 0.0477 grams of Pd(PPh3)2Cl2 (0.068 mmole, STREM) were dissolved in 25 ml of THF solution, heated for reflux for 3 hours, cooled down to stop the reaction, dried THF, and column separation purified, giving 0.71 grams of a product of 4,7-dithien-2-yl-2,1,3-benzothiadiazole, with a yield rate of 69%. 3 grams of 4,7-dithien-2-yl-2,1,3-benzothiadiazole, 30 ml of CH2Cl2 (Aldrich) were stirred till dissolved, and a mixed solution of 20 ml of HOAc and 4 ml of Br2 (Merck) was slowly added at room temperature for reaction for 18 hours, and the precipitate was washed with water, and re-precipitated with Dichloromethane (CH2Cl2, Merck), giving a black red solid. 1H NMR (400 MHz, CDCl3): δ (ppm) 7.787 (d, 4H, 4.0 Hz), 7.140 (d, 2H, 4 Hz).

The following reaction scheme illustrates the preparation of monomer m7:

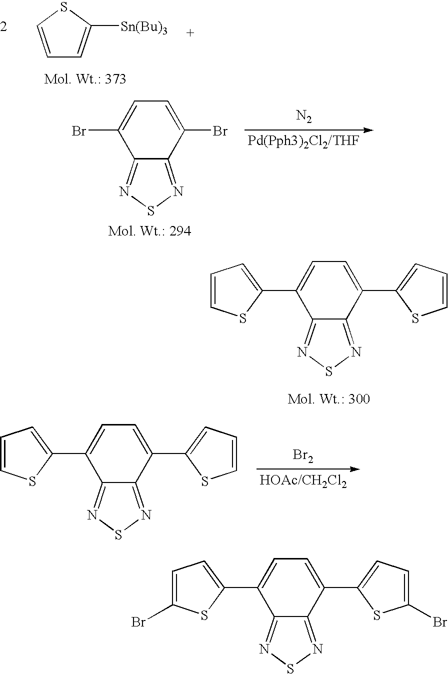

### PREPARING EXAMPLE 6

### Synthesis of Monomer m8 7

### 1,4-Bisbromomethyl-2,3-dibutoxy benzene

118.5 grams of Morpholine (Aldrich), 41grams of formaldehyde (Merck), 500 ml of IPA (ACROS) were placed in a 1000 ml dual-neck vase, heated to 95° C., and added 50 grams of catechol (TCI), at 95° C. for reaction for 2.5 hours. 100 ml of EA (ACROS) was added at room temperature, stirred for 30 minutes, and filtered, giving a solid, and added 300 ml of EA, heated to 60° C., stirred, cooled down, filtered, and washed with EA, giving 82 grams of a solid DBI, with a yield rate of 58.6%.

56.5 grams of DBI, 1000 ml of EtOH (99.5%, Merck), 100 grams of K2CO3 (Aldrich), 113 grams of n-butyl bromide (Aldrich) were added, heated to reflux temperature for reaction for 69 hours, filtered, concentrated, and then the solvent was dried. 500 ml of EA was added, extracted with water, dried with MgSO4, filtered, and concentrated, giving 66.36 grams of a brown liquid (DB2), with a yield rate of 86.1%.

66.36 grams of DB2, 210 ml of CH3COOH (ACROS), 91 grams of CH3COONa (Aldrich), 105 ml of acetic anhydride (Merck) were placed in a 1000 ml dual-neck vase, heated to 103° C. for reaction for 89 hours, extracted with water and EA, dried with MgSO4, filtered, and concentrated, giving 65.24 grams of a brown liquid (DB3). 200 ml of HBr (33% in glacial acetic acid, Aldrich) was added, and reacted at room temperature for 2.5 hours. The reaction solution was extracted with water and EA, dried with MgSO4, filtered, and concentrated, giving 64.4 grams of a brown liquid, and then decolored by active carbon, and re-crystallized with methanol, giving a white solid. 1H NMR (400 MHz, CDCl3): δ (ppm) 7.082 (s, 2H), 4.519 (s, 4H), 4.086 (t, 4H, 6.7 Hz), 1.798 (m, 4H ), 1.534 (m, 4H ), 1.002 (t, 6H, 7.3Hz ).

The following reaction scheme illustrates the preparation of monomer m8:

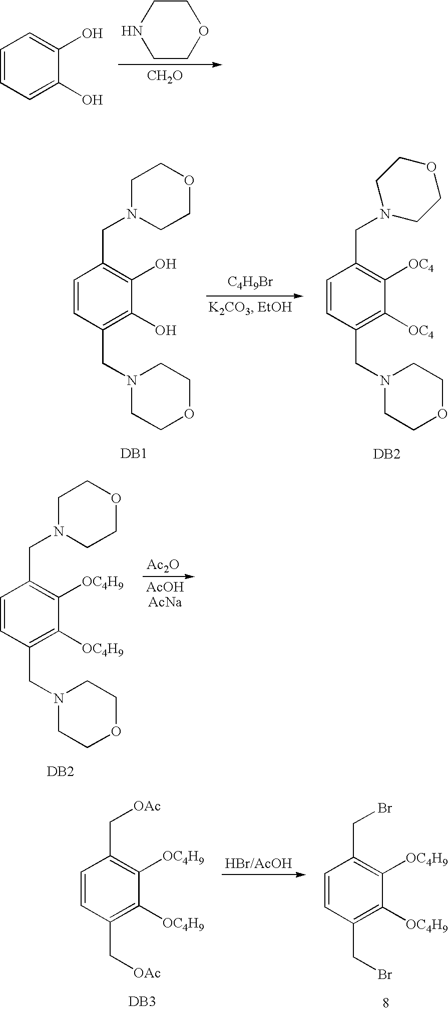

### PREPARING EXAMPLE 7

### Copolymerization Steps of Biphenyl Fluorene and Another Conjugated Monomers

The green, yellow, and red fluorescent polymers of Formula (I, II) were copolymerized through Yamamoto coupling reaction, using the monomer m1 or m2 as the major molecule combined with the monomers m3˜m7. The polymerization method of yellow phenanthrene copolymer is described in detail as below, the other copolymers such as green and red fluorescent polymers are copolymerized by the same way:

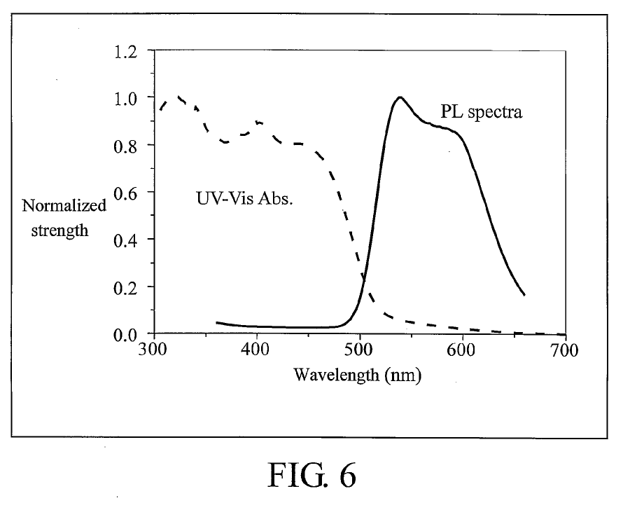

Under dewater, degas, 2.91 grams of Bis(1,5-cyclooctadiene)Nickle, (10.59mmole, Ni(COD)₂, Stream), 1.65 g 2,2-Bipyridyl (BPY, Aldrich), 1.3 ml cis,cis-1,5-Cyclooctadiene (10.59 mmole COD, Aldrich ), 5 ml anhydrous THF (Merk) were placed in a 50 ml reaction vase, heated to 80° C., stirred for 30 minutes, and under nitrogen, the monomer dissolved in anhydrous THF was added to the mixture. The kinds and the ratio of the monomers was m2: m3: m6: m7=65 (1.87 g, 2.29 mmole): 19.9 (0.23 g, 0.7 mmole): 15 (0.17 g, 0.53 mmole ): 0.1 (0.014 g, 0.03 mole), and was reacted at 80° C. for two days, and then 0.15 grams of 4-tert-butylbenzyl bromide (0.7 mmole, Aldrich), 10 ml of anhydrous THF were added for reaction for 24 hours. After the reaction was completed, the sample was put into 1000 ml of THF, and 1 c.c. of HCl was added and stirred for 2 hours, filtered, and column separation to remove the metal catalyst. The resulted product was re-precipitated with methanol, washed by methanol, and vacuum dried to remove the remained solvent, giving an orange solid of about 0.8 grams, with a yield rate of 40%. GPC: Mw=42K dalton, PDI=2.7. UV absorb peak (UV-Vis, film) was about 323, 397, 445 nm, and PL peak was about 543, 590nm. The UV-Vis absorb spectrum and the PL spectrum are shown in FIG. 6.

The following reaction scheme illustrates the preparation of biphenyl fluorene fluorescent copolymer, wherein m:n:p:q=65:19.9:15:0.1:

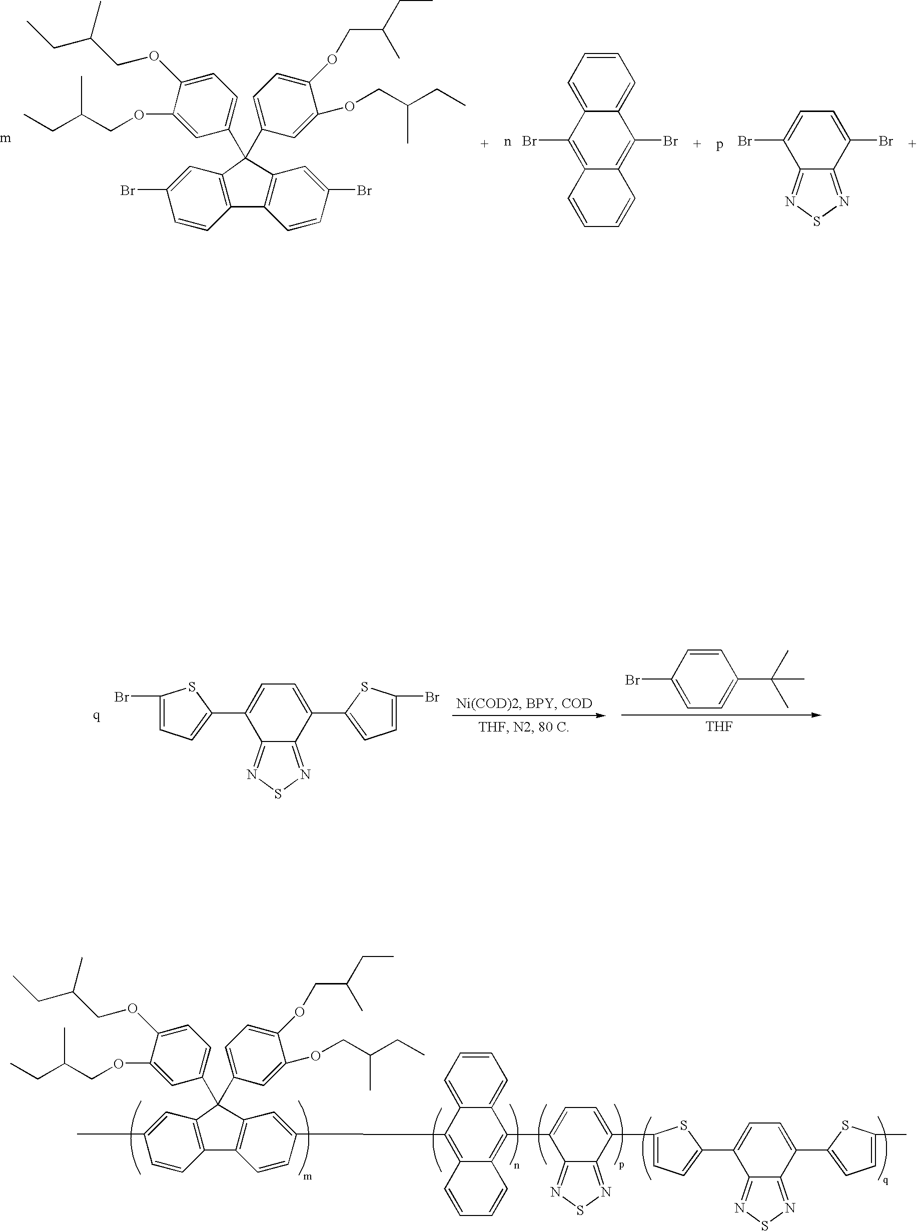

### PREPARING EXAMPLE 8

### Polymerization Steps of PPV Fluorescent Polymer

The fluorescent polymer of the copolymer derivatives of Formula (III) were copolymerized through Gilch dehydrohalogenation condensation polymerization, using the monomers m8 and m9 with different ratios to form green, yellow, and orange fluorescent polymers.

3 grams of m8 monomer (7.4 mmole) and 0.158 grams of m9 monomer (0.39 mmole) were placed in a tetra-neck vase, baked to dry, and under nitrogen, 300 ml of anhydrous THF was added, stirred until dissolved, giving a transparent colorless liquid. 60 ml of t-BuOK (Aldrich, conc.1M in THF) was added in the tetra-neck vase, giving a yellow solution, and under nitrogen, left at room temperature for reaction for 24 hours (Gilch dehydrohalogenation condensation polymerization), giving a yellow-green fluorescent dense liquid. The high viscous liquid was slowly put in a cup of MeOH, giving a yellow gel, and filtered, and put in a vase to vacuum dry, giving a yellow fiber-shaped solid. The yellow fiber-shaped solid was dissolved in THF again, and dripped slowly in a cup of MeOH, giving a gel, filtered, and put in a vase to vacuum dry, giving a yellow fiber-shaped solid with a weight average molecular weight (Mw) of about 770 k Dalton, PDI=4.2. UV-Vis Absorb spectrum (film) of 467, 497 nm, and PL spectrum (film) of 578 nm.

The following reaction scheme illustrates the preparation of PPV copolymer:

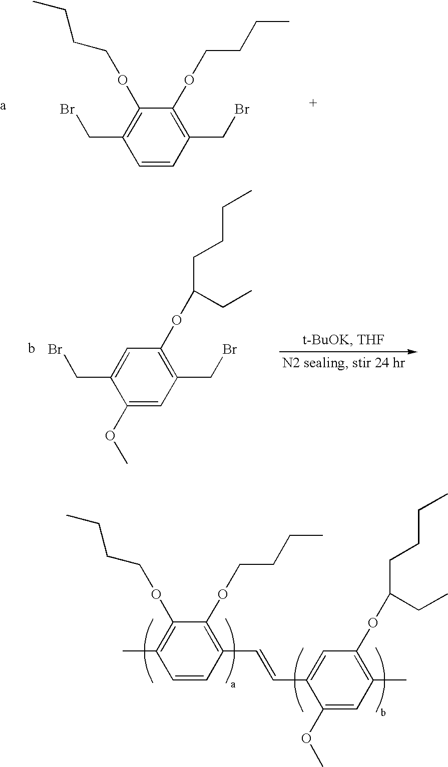

### EXAMPLE 1

### Fluorescent Polymer Copolymer Composition

According to the synthesis of the monomers and the polymerization methods as previously described above, several monomers with different molar percentages are copolymerized to form eight fluorescent polymer compositions with different colors as shown in the Table 1.

TABLE 1
The fluorescent polymers of green, yellow, orange, and red lights
copolymerized according the invention

| | | UV-Vis | | |
|---|---|---|---|---|
| | | Abs. | PL | Molecular |
| | fluorescent polymer | spectrum | spectrum | weight |
| No. | composition | (nm) | (nm) | (Mw)/K |
| 1 | -(m1)₆₀-(m6)₄₀- | 340, 445 | 540 | 34 |
| 2 | -(m2)₅₀-(m6)₅₀- | 467 | 542 | 67 |
| 3 | -(m2)₅₀-(m5)₅₀- | 456 | 550 | 54 |
| 4 | -(m2)₅₀-(m4)₁₅-(m6)₃₅- | 356, 456 | 548 | 45 |
| 5 | -(m2)₆₅-(m3)_{19.9}-(m6)₁₅- | 323, 400, | 543, 590 | 42 |
| | (m7)_{0.1}- | 445 | | |
| 6 | -(m2)₆₀-(m4)₂₅-(m6)₁₀-(m7)₅- | 356, 453 | 630 | 42 |
| 7 | -(m8)₁₀₀- | 445 | 536 | 370 |
| 8 | -(m8)₉₅-(m9)₅- | 475, 497 | 560 | 330 |

### Example 2

### Photo Curable Fluorescent Color Conversion Ink

According to Example 1, the eight fluorescent polymers are used to form the photo curable fluorescent color conversion ink, and the ratio thereof is shown in Table 2. The preparation method is described as below:

0.1 grams of fluorescent polymer was dissolved in a solvent, heated to 70° C. for dissolving completely, and cooled down to room temperature. Then, 2 c.c. of SMS-F9PGA: KT37 (9:1) was added to the fluorescent polymer solution, heated to 60° C. for dissolving completely. Using a Brookfield LVDV-II viscosimeter to measure the vixcosity of the solution, the results are shown in Table 2 below:

TABLE 2
The photo curable fluorescent color conversion ink compositions
containing the fluorescent polymer

| | fluorescent | SMS- | | | | |
|---|---|---|---|---|---|---|
| fluorescent | polymer | F9PGA:KT37/ | | Cyclohexone | THF | viscosity |
| material | No. (1 wt | 9:1 | Anisole | (wt | (wt | (cps@ |
| No | %) | (wt %) | (wt %) | %) | %) | 26 C.) |
| UVP1 | 1 | 20 | 30 | 5 | 44 | — |
| UVP2 | 2 | 20 | 64 | 5 | 10 | 2.54 |
| UVP3 | 3 | 20 | 54 | 5 | 20 | 2.2 |
| UVP4 | 4 | 20 | 74 | 5 | — | 2.8 |
| UVP5 | 5 | 20 | 64 | 5 | 10 | 2.42 |
| UVP6 | 6 | 20 | 74 | 5 | — | 2.3 |
| UVP7 | 7 | 20 | 74 | 5 | — | 38.4 |
| UVP8 | 8 | 20 | 54 | 5 | 20 | 23.1 |

### EXAMPLE 3

### Thermal Curable Fluorescent Color Conversion Ink Composition

According to Example 1, several fluorescent polymers are selected to form the thermal curable fluorescent color conversion ink, and the ratio thereof is shown in Table 3. The preparation method is described as below:

0.1 grams of SMS-914PG and 0.005 grams of DICY: BDMA (9:1) was dissolved in 2 c.c. of THF and pyrrolidine co-solvent for dissolving completely. Then, the mixture was added to the fluorescent polymer solution, heated to 60° C. for dissolving completely. The results are shown in Table 3 below:

TABLE 3
The thermal curable fluorescent color conversion ink compositions
containing the fluorescent polymer

| | fluorescent | | | | | |
|---|---|---|---|---|---|---|
| fluorescent | polymer | SMS- | DICY:BDMA/ | | | |
| material | No. (1 wt | F914PG | 9:1 | Anisole | THF | Pyrrolidine |
| No | %) | (wt %) | (wt %) | (wt %) | (wt %) | (wt %) |
| HP-1 | 4 | 10 | 0.5 | 20 | 58.5 | 10 |
| HP-2 | 5 | 10 | 0.5 | 30 | 48.5 | 10 |
| HP-3 | 6 | 10 | 0.5 | 30 | 48.5 | 10 |
| HP-4 | 7 | 10 | 0.5 | — | 78.5 | 10 |
| HP-5 | 8 | 10 | 0.5 | — | 78.5 | 10 |

### EXAMPLE 4

### Spin Coating and Inkjet Printing the Photo Curable Ink to Form a Film

The ink of Example 2 was spin coated by 1000rpm on a glass substrate to form a film, then cured by a UV light of 180 mj/cm2 and wavelength at 360 nm for 2 seconds, giving a film with a thickness of 0.1˜0.15 μm. The thickness of the film can be increased by repeating the above steps. Moreover, two inks of UVP-4 and UVP-6 were selected to inkjet print for comparison. Through a piezoelectricity controlled mechanism and a Xaar 128 inkjet printer head, with frequency of 1K Hz and substrate moving speed of 200 mm/sec, the inks of UVP-4 and UVP-6 were inkjet printed on a glass plate to form inkjet printed points having a diameter of 80 μm. Accordingly, the fluorescent ink composition of the invention is suitable for inkjet printing to form a film.

### EXAMPLE 5

### Spin Coating the Thermal Curable Ink and the Ink Consisted of the Thermal Curable and the Photo Curable Inks to Form the Films

The ink of Example 3 was spin coated by 1000 rpm on a glass substrate to form a film, then cured by baking at 90° C. for 30 minutes, and then cured by baking at 150° C. for 30 minutes, giving a film with a thickness of about 0.15-0.2 μm. The thickness of the film can be increased by repeating the above steps. Moreover, one photo curable ink of UVP 4-8 and one thermal curable ink of HP 1-5 were mixed by a ratio of 4:1 to from an ink composition and then spin coated or dipped on a glass plate to form a film. According to the crosslinking curing methods of the examples 4 and 5, first photo curing and then thermal curing was performed to complete a fluorescent color conversion film formed from the photo and the thermal curable inks.

### EXAMPLE 6

### Fabrication and Testing of a Color Conversion Module

According to a plane backlight source design, a blue LED plane backlight source of FIG. 5 was fabricated, which had a brightness of 80 cd/cm2 while under a voltage of 9V and a current of 10.1 mA (Keithely 2400 Multimeter). The blue LED plane backlight source was taken as a first light source. The color conversion film formed of the examples 4 and 5 was excited by the first light source to produce a second light source of a white light, or a white light could have been formed by mixing the first light source and the second light source. The measurement results were taken by a brightness meter of BM-7/TOPCON as shown in Table 4 below.

TABLE 4
CIE chromaticity coordinate and the brightness of a blue LED plus a
fluorescent color conversion film

| | chromaticity | | |
|---|---|---|---|
| | coordinate | brightness | photoluminescence |
| | CIE (x, y) | (cd/m2) | efficiency (%) |
| blueLED | 0.14, 0.05 | 83 | — |
| BLED + UVP1 | 0.32, 0.36 | 31.5 | 38.0 |
| BLED + UVP2 | 0.39, 0.58 | 59.5 | 71.7 |
| BLED + UVP3 | 0.33, 0.47 | 49.6 | 59.8 |
| BLED + UVP4 | 0.29, 0.42 | 37.2 | 44.8 |
| BLED + UVP5 | 0.32, 0.33 | 122.0 | 147 |
| BLED + UVP6 | 0.40, 0.30 | 42.0 | 50.6 |
| BLED + UVP7 | 0.33, 0.49 | 60.3 | 72.65 |
| BLED + UVP8 | 0.53, 0.44 | 45.5 | 54.8 |
| BLED + HP1 | 0.34, 0.26 | 63.1 | 76.0 |
| BLED + HP3 | 0.38, 0.28 | 44.8 | 54.0 |

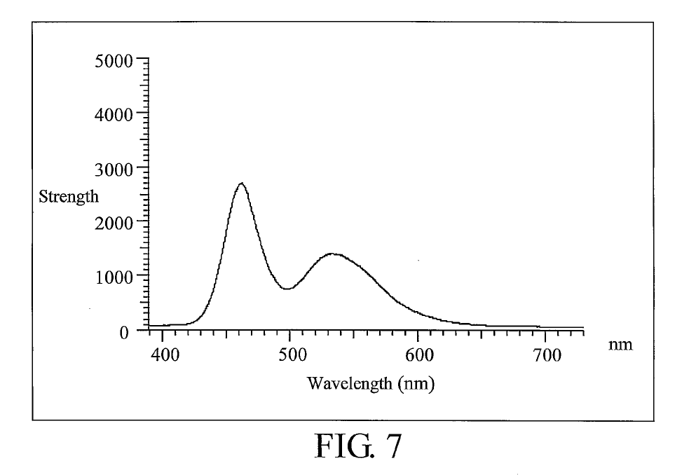

As shown in Table 4, the blue LED plus the color conversion film (UVP5) containing a yellow fluorescent polymer (No. 5) can transfer the blue light source of LED into a yellow light source, and then be mixed with the blue light source of LED and the yellow light source can get a white light source. FIG. 7 shows a white luminescence spectrum of a blue LED backlight source plus a color conversion film of a yellow light polymer (blue LED+UVP5), with a chromaticity coordinate CIE (x, y): 0.32, 0.33. Additionally, the blue LED plus the color conversion film (UVP2, UVP7, or UVP8) containing a green and a red fluorescent polymer can transfer the blue light source of an LED into a green and a red light sources. Moreover, the thickness of the color conversion film can affect the CIE chromaticity coordinate and the efficiency thereof.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An ink composition of a color conversion film, comprising:
a fluorescent polymer;
an aromatic transparent unsaturated resin containing a phenyl or fluorene functional group; and
a solvent of a cyclic compound,
wherein the molecular structure of the aromatic transparent unsaturated resin is compatible to the molecular structure of the fluorescent polymer.

2. The ink composition as claimed in claim 1, wherein the fluorescent polymer comprises a phenanthrene derivative copolymer of formula (I): 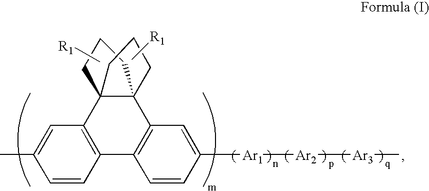
wherein each Ar₁, Ar₂, and Ar₃ is independently selected from: 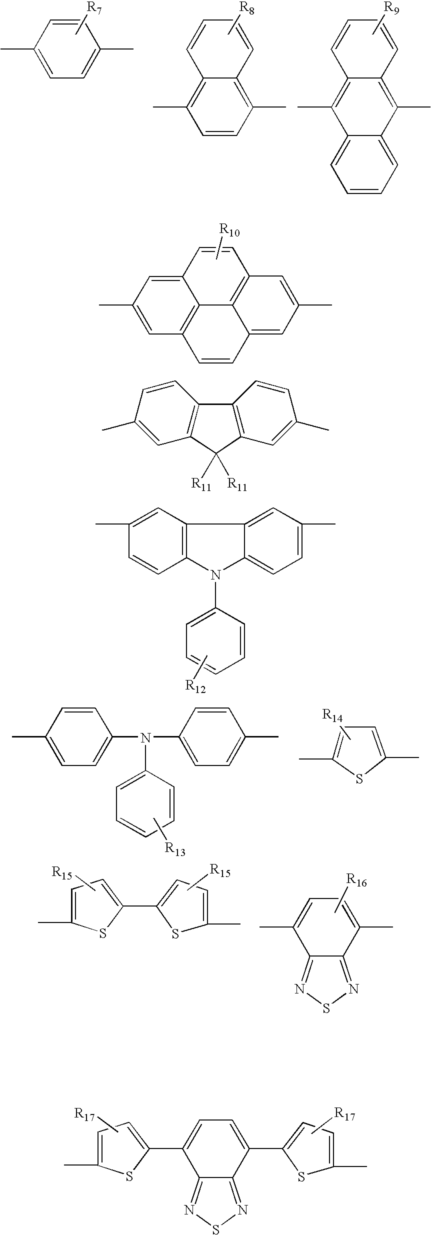
and each R₁ is independently hydrogen, hydroxyl, carboxyl group, aldehyde group, keto group, straight-chain or branched-chain C₁₋₂₂ alkyl, straight-chain or branched-chain C₁₋₂₂ alkoxy, ortho-, meta-, or para-alkyl phenoxy,
wherein each R₇˜R₁₇ is independently hydrogen, straight-chain or branched-chain C₁₋₂₂ alkyl, or straight-chain or branched-chain C₁₋₂₂ alkoxy, and
each m, n, p, and q of formula (I) is the number of repeated units, wherein the ratio of m in formula (I) is at least more than 50%.

3. The ink composition as claimed in claim 1, wherein the fluorescent polymer comprises a biphenyl fluorene derivative copolymer of formula (II): 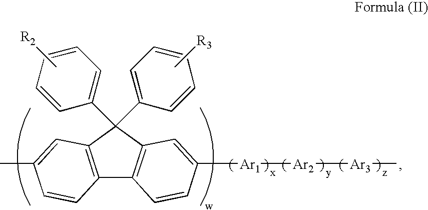
wherein each Ar₁, Ar₂, and Ar₃ is independently selected from: 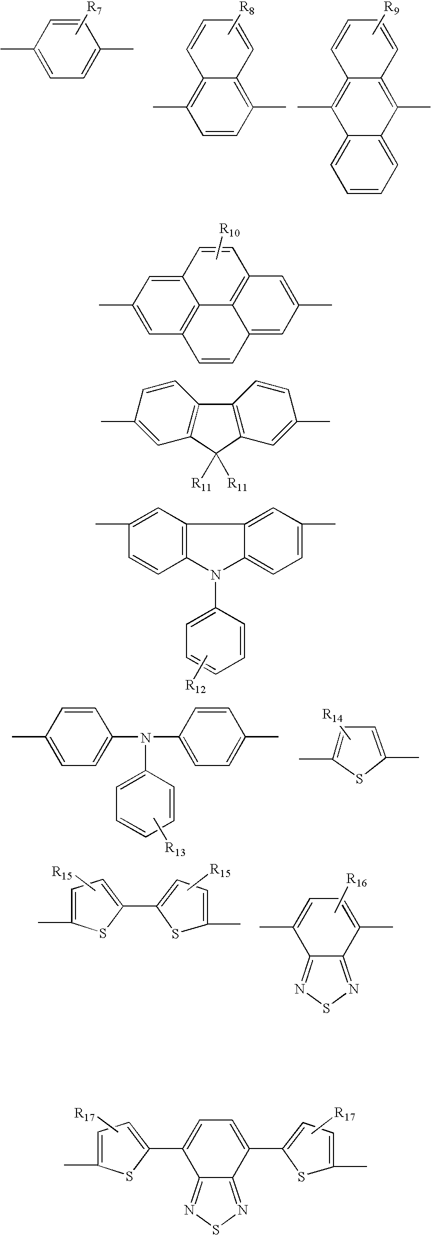
and each R₂, R₃ is independently hydrogen, hydroxyl, carboxyl group, aldehyde group, straight-chain or branched-chain C₁₋₂₂ alkyl, straight-chain or branched-chain C₁₋₂₂ alkoxy, ortho-, meta-, or para-alkyl phenoxy,
wherein each R₇˜R₁₇ is independently hydrogen, straight-chain or branched-chain C₁₋₂₂ alkyl, or straight-chain or branched-chain C₁₋₂₂ alkoxy, and
each w, x, y, and z of formula (II) is the number of repeated units, wherein the ratio of w in formula (II) is at least more than 50%.

4. The ink composition as claimed in claim 1, wherein the fluorescent polymer comprises a poly(p-phenylene vinylene) (PPV) polymer of formula (III): 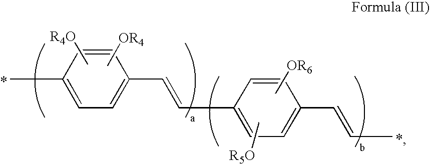
, wherein each R₄˜R₆ is independently straight-chain or branched-chain C₁₋₂₂ alkyl, ortho-, meta-, or para-alkyl phenyl or ortho-, meta-, or para-alkyl phenoxy, and each a and b of formula (III) is the number of repeated units, and the ratio of a in formula (III) is at least more than 50%.

5. The ink composition as claimed in claim 1, wherein the aromatic transparent unsaturated resin comprises a thermo curable fluorine or phenyl epoxide resin of formula (IV): 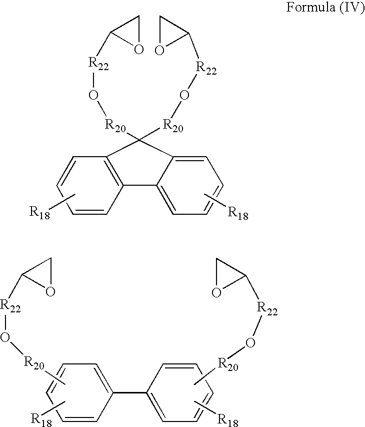
, wherein each R₁₈ is independently hydrogen, straight-chain or branched-chain C₁₋₆ alkyl, straight-chain or branched-chain C₁₋₆ alkoxy, ortho-, meta-, or para-alkyl phenyl, ortho-, meta-, or para-alkyl phenoxy, or ortho-, meta-, or para-phenolic group, and each R₂₀ is independently C₁₋₆ carbon chain, ortho-, meta-, or para-phenyl, ortho-, meta-, or para-phenolic group, ortho-, meta-, or para-alkyl phenyl, and each R₂₂ is independently C₁₋₆ carbon chain.

6. The ink composition as claimed in claim 1, wherein the aromatic transparent unsaturated resin comprises a photo-curable fluorine or phenyl acryl resin of formula (V): 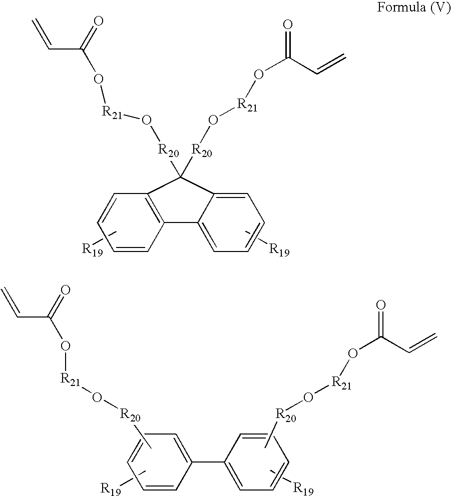
, wherein each R₁₉ is independently hydrogen, straight-chain or branched-chain C₁₋₆ alkyl, straight-chain or branched-chain C₁₋₆ alkoxy, ortho-, meta-, or para-alkyl phenyl, or ortho-, meta-, or para-phenolic group, and each R₂₀ is independently C₁₋₆ carbon chain, ortho-, meta-, or para-phenyl, ortho-, meta-, or para-alkyl phenyl, ortho-, meta-, or para-phenolic group, and each R₂₁ is independently C₁₋₆ carbon chain.

7. The ink composition as claimed in claim 1, wherein the solvent comprises tetrahydrofuran (THF), anisole, cyclohexone, pyridine, pyrrolidine, toluene, xylene, phenol, trimethyl benzene, aniline, methylaniline, dimethylaniline, toluidine or the combinations thereof.

8. The ink composition as claimed in claim 1, further comprising an optical micro-particle, wherein the optical micro-particle comprises polyethylene (PE), polymethylmethacrylate (PMMA), SiO₂ or the combinations thereof.

9. The ink composition as claimed in claim 1, further comprising a photoinitiator, a curing agent, an accelerator, an anti-oxidant or the combinations thereof.

10. The ink composition as claimed in claim 1, wherein the fluorescent polymer has a ultraviolet-visible (UV-Vis) absorption spectrum at about 390 to 490 nm.

11. The ink composition as claimed in claim 1, wherein the solvent comprises one or more than one solvent with a boiling point of 60 to 200° C.

12. The ink composition as claimed in claim 1, wherein the fluorescent polymer is about 0.5 to 10% by weight.

13. The ink composition as claimed in claim 1, wherein the aromatic transparent unsaturated resin is about 10 to 40% by weight.

14. The ink composition as claimed in claim 1, wherein the solvent is about 40 to 80% by weight.

15. The ink composition as claimed in claim 9, wherein the curing agent is about 0.5 to 3% by weight.

16. The ink composition as claimed in claim 9, wherein the photoinitiator is about 1 to 5% by weight.

17. The ink composition as claimed in claim 8, wherein the optical micro-particle is about 1 to 5% by weight.

18. A fabrication method of a color conversion film, comprising:
dispensing the ink composition as claimed in claim 1 on a substrate; and
curing the ink composition to form the color conversion film.

19. The method as claimed in claim 18, wherein the step of dispensing the ink composition comprises die coating, blade coating, spray coating, inkjet printing, stamping, flexographic printing, plate printing, or screen printing.

20. The method as claimed in claim 18, wherein the substrate comprises a blue light-emitting diode (LED) die, a UV light-emitting diode (LED) die, a light guide plate or a transparent substrate.

21. The method as claimed in claim 20, wherein the substrate is the blue LED die, and the fluorescent polymer of the ink composition absorbs a first light from the blue LED die and turns the first light into a second light.

22. The method as claimed in claim 21, wherein the first light and the second light are mixed into a white light, and a white light-emitting diode having a color temperature of about 2000K to about 8000K is formed.

23. The method as claimed in claim 20, wherein the substrate is the UV LED die, and the fluorescent polymer of the ink composition absorbs a first light from the UV LED die and turns the first light into a second light.

24. The method as claimed in claim 23, wherein the second light comprises a red light, a green light and a blue light which are mixed into a white light, and a white light-emitting diode having a color temperature of about 2000K to about 8000K is formed.

25. The method as claimed in claim 20, wherein the substrate is the transparent substrate, and the ink composition is inkjet printed on the transparent substrate to form an array of a plurality of pixels.

26. The method as claimed in claim 25, further comprising providing a blue LED light source or a UV LED light source disposed under the transparent substrate, wherein the fluorescent polymer of the ink composition turns the blue LED or the UV LED light source into a light source containing a red light, a green light and a blue light, and the color conversion film is a color filter of a liquid crystal display.
